(19) United States
(12) Patent Application Publication
(10) Pub. No.: US 2017/0306490 A1
(43) Pub. Date: Oct. 26, 2017

(54) Enhanced Spatial ALD Of Metals Through Controlled Precursor Mixing

(71) Applicant: Applied Materials, Inc., Santa Clara, CA (US)

(72) Inventors: Kelvin Chan, San Ramon, CA (US); Yihong Chen, San Jose, CA (US); Jared Ahmad Lee, San Jose, CA (US); Kevin Griffin, Livermore, CA (US); Srinivas Gandikota, Santa Clara, CA (US); Joseph Yudovsky, Campbell, CA (US); Mandyam Sriram, San Jose, CA (US)

(21) Appl. No.: 15/494,892

(22) Filed: Apr. 24, 2017

Related U.S. Application Data
(60) Provisional application No. 62/327,091, filed on Apr. 25, 2016.

(51) Int. Cl. C23C 16/455; C23C 16/50

(52) U.S. Cl. CPC C23C 16/45527; C23C 16/50

(57) ABSTRACT

Methods of depositing a film by atomic layer deposition are described. The methods comprise exposing a substrate surface to a first process condition comprising a first reactive gas and a second reactive gas and exposing the substrate surface to a second process condition comprising the second reactive gas. The first process condition comprises less than a full amount of the second reactive gas for a CVD process.

### CROSS-REFERENCE TO RELATED APPLICATIONS

This application claims priority to U.S. Provisional Application No. 62/327,091, filed Apr. 25, 2016, the entire disclosure of which is hereby incorporated by reference herein.

### TECHNICAL FIELD

The present disclosure relates generally to apparatus and methods of depositing thin films. In particular, the disclosure relates to apparatus and methods for depositing spatial ALD films with controlled precursor mixing.

### BACKGROUND

Spatial ALD relies on spatial separation of precursors. Film growth happens when a substrate moves from one precursor zone to another. As the substrate repeatedly moves between the two zones, continual growth is realized. One example is tungsten spatial ALD in which one precursor zone is filled with WF₆ and another precursor zone is filled with H₂. In each zone, the precursor may or may not be diluted with argon. One exposure cycle means the substrate having traveled through one WF₆ zone and one H₂ zone.

Growth rates are typically below 0.2 angstroms/cycle for the spatial ALD of tungsten at substrate temperatures between 200 and 450 degrees Celsius. There is a need in the art for methods of depositing films by spatial ALD with greater growth rates.

### SUMMARY

One or more embodiments of the disclosure are directed to methods of depositing a film by atomic layer deposition. The methods comprise exposing a substrate surface to a first process condition comprising a first reactive gas and a second reactive gas and exposing the substrate surface to a second process condition comprising the second reactive gas. The first process condition comprises less than a full amount of the second reactive gas for a CVD process.

Additional embodiments of the disclosure are directed to methods comprising exposing a substrate surface to a first process condition comprising a first reactive gas and a second reactive gas. The first reactive gas and the second reactive gas being spontaneously reactive. The substrate surface is exposed to a second process condition consisting essentially of the second reactive gas. The first process condition comprises less than a full amount of the second reactive gas for CVD.

Further embodiments of the disclosure are directed to methods comprising exposing a substrate surface to a first process condition in a first process region of a processing chamber. The first process condition comprises a constant flow of a first reactive gas comprising WF₆ and a pulsed flow of a second reactive gas consisting essentially of H₂. The second reactive gas pulsed so that there is less than a full amount of the second reactive gas for CVD. The substrate is laterally moved through a gas curtain from the first process region to a second process region of the processing chamber. The gas curtain comprising one or more of a purge gas stream and/or a vacuum region. The substrate surface is exposed to a second process condition in the second process region. The second process condition consisting essentially of H₂. The substrate is laterally moved through a gas curtain from the second process region. The gas curtain comprises one or more of a purge gas stream and/or a vacuum region. Exposures to the first process condition and the second process condition are repeated to deposit a film of a predetermined thickness.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional view of a batch processing chamber in accordance with one or more embodiment of the disclosure;

FIG. 2 shows a partial perspective view of a batch processing chamber in accordance with one or more embodiment of the disclosure;

FIG. 3 shows a schematic view of a batch processing chamber in accordance with one or more embodiment of the disclosure;

FIG. 4 shows a schematic view of a portion of a wedge shaped gas distribution assembly for use in a batch processing chamber in accordance with one or more embodiment of the disclosure; and

FIG. 5 shows a schematic view of a batch processing chamber in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface.

Some embodiments of the disclosure are directed to processes that use a reaction chamber with multiple gas ports that can be used for introduction of different chemicals or plasma gases. Spatially, these gas ports (also referred to as channels) are separated by inert purging gases and/or vacuum pumping holes to create a gas curtain that minimizes or eliminates mixing of gases from different gas ports to avoid unwanted gas phase reactions. Wafers moving through these different spatially separated ports get sequential and multiple surface exposures to different chemical or plasma environment so that layer by layer film growth in spatial ALD mode or surface etching process occur. In some embodiments, the processing chamber has modular architectures on gas distribution components and each modular component has independent parameter control (e.g., RF or gas flow) to provide flexibility to control, for example, gas flow and/or RF exposure.

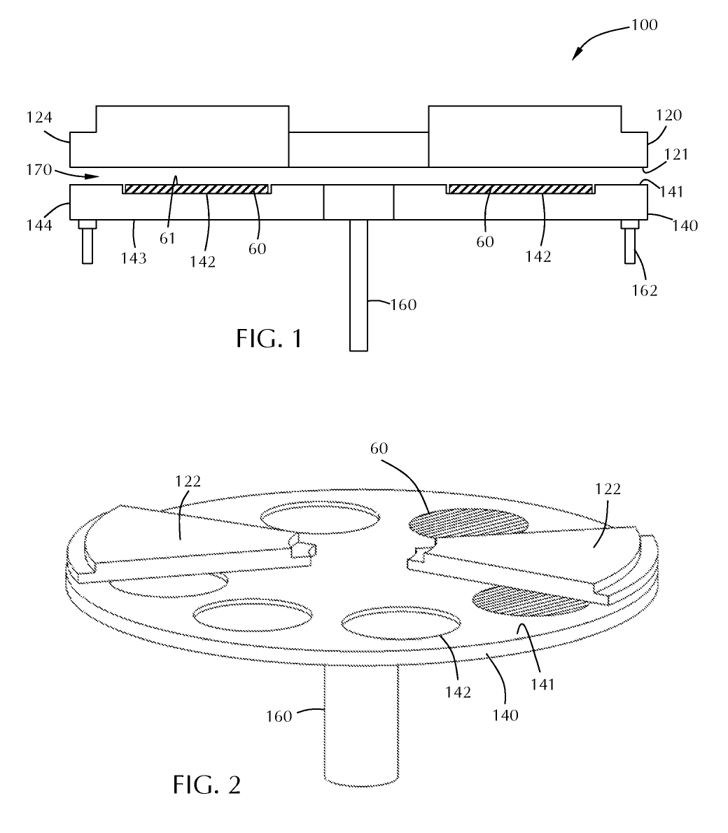

Embodiments of the disclosure are directed to apparatus and methods to provide enhanced chemical exchange in a batch processing chamber, also referred to as a spatial processing chamber. FIG. 1 shows a cross-section of a processing chamber 100 including a gas distribution assembly 120, also referred to as injectors or an injector assembly, and a susceptor assembly 140. The gas distribution assembly 120 is any type of gas delivery device used in a processing chamber. The gas distribution assembly 120 includes a front surface 121 which faces the susceptor assembly 140. The front surface 121 can have any number or variety of openings to deliver a flow of gases toward the susceptor assembly 140. The gas distribution assembly 120 also includes an outer edge 124 which in the embodiments shown, is substantially round.

The specific type of gas distribution assembly 120 used can vary depending on the particular process being used. Embodiments of the disclosure can be used with any type of processing system where the gap between the susceptor and the gas distribution assembly is controlled. In a binary reaction, the plurality of gas channels can include at least one first reactive gas A channel, at least one second reactive gas B channel, at least one purge gas P channel and/or at least one vacuum V channel. The gases flowing from the first reactive gas A channel(s), the second reactive gas B channel(s) and the purge gas P channel(s) are directed toward the top surface of the wafer. Some of the gas flow moves horizontally across the surface of the wafer and out of the process region through the purge gas P channel(s). A substrate moving from one end of the gas distribution assembly to the other end will be exposed to each of the process gases in turn, forming a layer on the substrate surface.

In some embodiments, the gas distribution assembly 120 is a rigid stationary body made of a single injector unit. In one or more embodiments, the gas distribution assembly 120 is made up of a plurality of individual sectors (e.g., injector units 122), as shown in FIG. 2. Either a single piece body or a multi-sector body can be used with the various embodiments of the disclosure described.

A susceptor assembly 140 is positioned beneath the gas distribution assembly 120. The susceptor assembly 140 includes a top surface 141 and at least one recess 142 in the top surface 141. The susceptor assembly 140 also has a bottom surface 143 and an edge 144. The recess 142 can be any suitable shape and size depending on the shape and size of the substrates 60 being processed. In the embodiment shown in FIG. 1, the recess 142 has a flat bottom to support the bottom of the wafer; however, the bottom of the recess can vary. In some embodiments, the recess has step regions around the outer peripheral edge of the recess which are sized to support the outer peripheral edge of the wafer. The amount of the outer peripheral edge of the wafer that is supported by the steps can vary depending on, for example, the thickness of the wafer and the presence of features already present on the back side of the wafer.

In some embodiments, as shown in FIG. 1, the recess 142 in the top surface 141 of the susceptor assembly 140 is sized so that a substrate 60 supported in the recess 142 has a top surface 61 substantially coplanar with the top surface 141 of the susceptor 140. As used in this specification and the appended claims, the term “substantially coplanar” means that the top surface of the wafer and the top surface of the susceptor assembly are coplanar within ±0.5 mm. In some embodiments, the top surfaces are coplanar within ±0.4 mm, ±0.3 mm, ±0.2 mm, ±0.15 mm, ±0.10 mm or ±0.05 mm.

The susceptor assembly 140 of FIG. 1 includes a support post 160 which is capable of lifting, lowering and rotating the susceptor assembly 140. The susceptor assembly may include a heater, or gas lines, or electrical components within the center of the support post 160. The support post 160 may be the primary means of increasing or decreasing the gap between the susceptor assembly 140 and the gas distribution assembly 120, moving the susceptor assembly 140 into proper position. The susceptor assembly 140 may also include fine tuning actuators 162 which can make micro-adjustments to susceptor assembly 140 to create a predetermined gap 170 between the susceptor assembly 140 and the gas distribution assembly 120.

In some embodiments, the gap 170 distance is in the range of about 0.1 mm to about 5.0 mm, or in the range of about 0.1 mm to about 3.0 mm, or in the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The processing chamber 100 shown in the Figures is a carousel-type chamber in which the susceptor assembly 140 can hold a plurality of substrates 60. As shown in FIG. 2, the gas distribution assembly 120 may include a plurality of separate injector units 122, each injector unit 122 being capable of depositing a film on the wafer, as the wafer is moved beneath the injector unit. Two pie-shaped injector units 122 are shown positioned on approximately opposite sides of and above the susceptor assembly 140. This number of injector units 122 is shown for illustrative purposes only. It will be understood that more or less injector units 122 can be included. In some embodiments, there are a sufficient number of pie-shaped injector units 122 to form a shape conforming to the shape of the susceptor assembly 140. In some embodiments, each of the individual pie-shaped injector units 122 may be independently moved, removed and/or replaced without affecting any of the other injector units 122. For example, one segment may be raised to permit a robot to access the region between the susceptor assembly 140 and gas distribution assembly 120 to load/unload substrates 60.

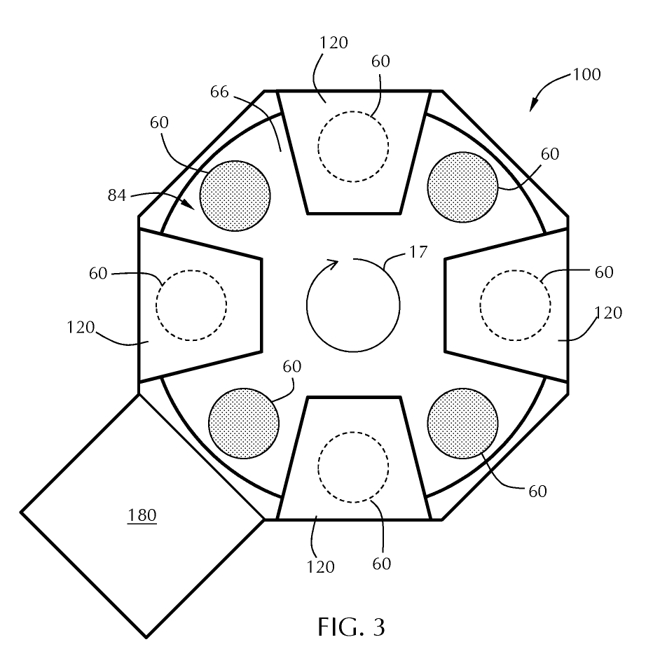

Processing chambers having multiple gas injectors can be used to process multiple wafers simultaneously so that the wafers experience the same process flow. For example, as shown in FIG. 3, the processing chamber 100 has four gas injector assemblies and four substrates 60. At the outset of processing, the substrates 60 can be positioned between the gas distribution assemblies 120. Rotating 17 the susceptor assembly 140 by 45° will result in each substrate 60 which is between gas distribution assemblies 120 to be moved to an gas distribution assembly 120 for film deposition, as illustrated by the dotted circle under the gas distribution assemblies 120. An additional 45° rotation would move the substrates 60 away from the gas distribution assemblies 120. The number of substrates 60 and gas distribution assemblies 120 can be the same or different. In some embodiments, there are the same numbers of wafers being processed as there are gas distribution assemblies. In one or more embodiments, the number of wafers being processed are fraction of or an integer multiple of the number of gas distribution assemblies. For example, if there are four gas distribution assemblies, there are 4× wafers being processed, where x is an integer value greater than or equal to one. In an exemplary embodiment, the gas distribution assembly 120 includes eight process regions separated by gas curtains and the susceptor assembly 140 can hold six wafers.

The processing chamber 100 shown in FIG. 3 is merely representative of one possible configuration and should not be taken as limiting the scope of the disclosure. Here, the processing chamber 100 includes a plurality of gas distribution assemblies 120. In the embodiment shown, there are four gas distribution assemblies (also called gas distribution assemblies 120) evenly spaced about the processing chamber 100. The processing chamber 100 shown is octagonal; however, those skilled in the art will understand that this is one possible shape and should not be taken as limiting the scope of the disclosure. The gas distribution assemblies 120 shown are trapezoidal, but can be a single circular component or made up of a plurality of pie-shaped segments, like that shown in FIG. 2.

The embodiment shown in FIG. 3 includes a load lock chamber 180, or an auxiliary chamber like a buffer station. This chamber 180 is connected to a side of the processing chamber 100 to allow, for example the substrates (also referred to as substrates 60) to be loaded/unloaded from the chamber 100. A wafer robot may be positioned in the chamber 180 to move the substrate onto the susceptor.

Rotation of the carousel (e.g., the susceptor assembly 140) can be continuous or intermittent (discontinuous). In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the carousel can pause again. Pausing between the injectors may provide time for additional processing steps between each layer deposition (e.g., exposure to plasma).

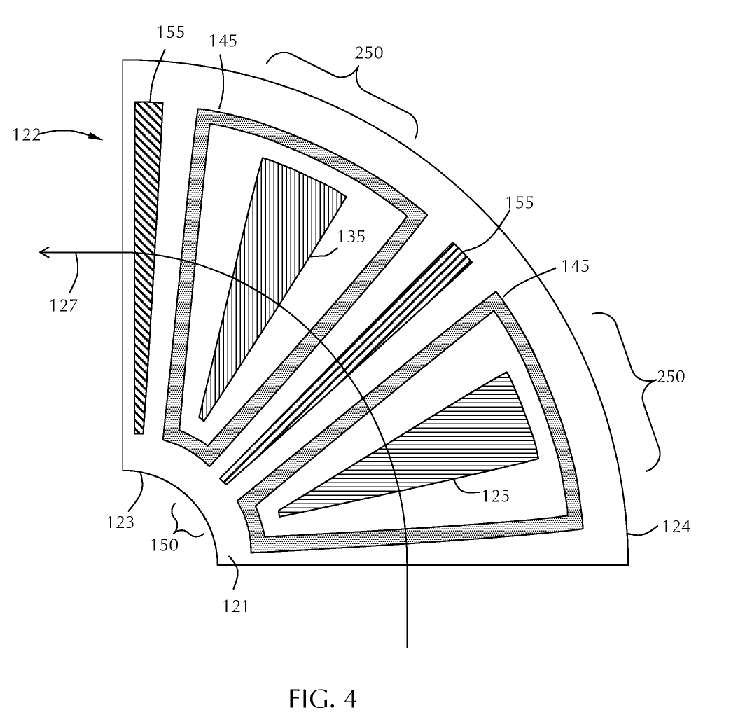

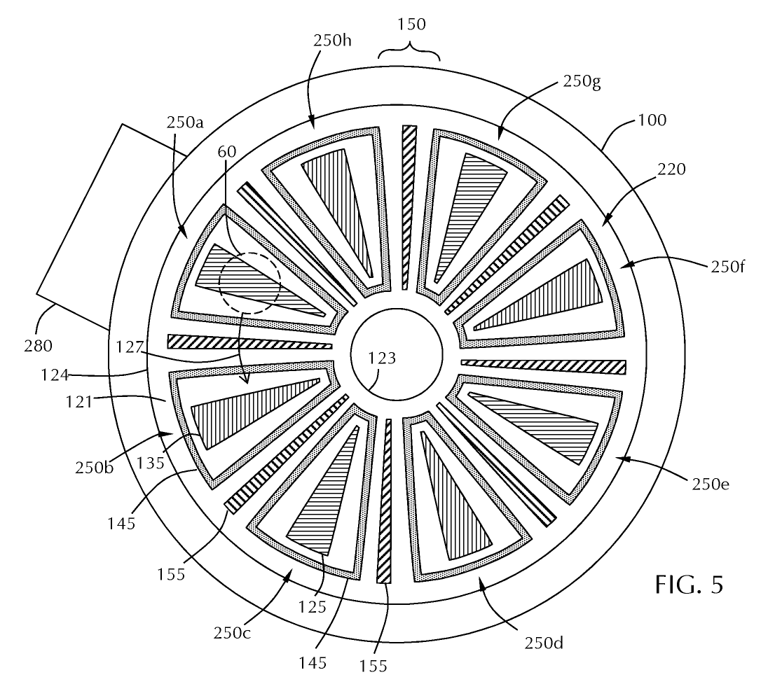

FIG. 4 shows a sector or portion of a gas distribution assembly 220, which may be referred to as an injector unit 122. The injector units 122 can be used individually or in combination with other injector units. For example, as shown in FIG. 5, four of the injector units 122 of FIG. 4 are combined to form a single gas distribution assembly 220. (The lines separating the four injector units are not shown for clarity.) While the injector unit 122 of FIG. 4 has both a first reactive gas port 125 and a second gas port 135 in addition to purge gas ports 155 and vacuum ports 145, an injector unit 122 does not need all of these components.

Referring to both FIGS. 4 and 5, a gas distribution assembly 220 in accordance with one or more embodiment may comprise a plurality of sectors (or injector units 122) with each sector being identical or different. The gas distribution assembly 220 is positioned within the processing chamber and comprises a plurality of elongate gas ports 125, 135, 145 in a front surface 121 of the gas distribution assembly 220. The plurality of elongate gas ports 125, 135, 145, 155 extend from an area adjacent the inner peripheral edge 123 toward an area adjacent the outer peripheral edge 124 of the gas distribution assembly 220. The plurality of gas ports shown include a first reactive gas port 125, a second gas port 135, a vacuum port 145 which surrounds each of the first reactive gas ports and the second reactive gas ports and a purge gas port 155.

With reference to the embodiments shown in FIG. 4 or 5, when stating that the ports extend from at least about an inner peripheral region to at least about an outer peripheral region, however, the ports can extend more than just radially from inner to outer regions. The ports can extend tangentially as vacuum port 145 surrounds reactive gas port 125 and reactive gas port 135. In the embodiment shown in FIGS. 4 and 5, the wedge shaped reactive gas ports 125, 135 are surrounded on all edges, including adjacent the inner peripheral region and outer peripheral region, by a vacuum port 145.

Referring to FIG. 4, as a substrate moves along path 127, each portion of the substrate surface is exposed to the various reactive gases. To follow the path 127, the substrate will be exposed to, or “see”, a purge gas port 155, a vacuum port 145, a first reactive gas port 125, a vacuum port 145, a purge gas port 155, a vacuum port 145, a second gas port 135 and a vacuum port 145. Thus, at the end of the path 127 shown in FIG. 4, the substrate has been exposed to the first reactive gas 125 and the second reactive gas 135 to form a layer. The injector unit 122 shown makes a quarter circle but could be larger or smaller. The gas distribution assembly 220 shown in FIG. 5 can be considered a combination of four of the injector units 122 of FIG. 4 connected in series. The path 127 shown in FIG. 4 is represented as counter-clockwise; however, those skilled in the art will understand that the path can be reversed and/or the order of gas ports can be reversed.

The injector unit 122 of FIG. 4 shows a gas curtain 150 that separates the reactive gases. The term “gas curtain” is used to describe any combination of gas flows or vacuum that separate reactive gases from mixing. The gas curtain 150 shown in FIG. 4 comprises the portion of the vacuum port 145 next to the first reactive gas port 125, the purge gas port 155 in the middle and a portion of the vacuum port 145 next to the second gas port 135. This combination of gas flow and vacuum can be used to prevent or minimize gas phase reactions of the first reactive gas and the second reactive gas.

Referring to FIG. 5, the combination of gas flows and vacuum from the gas distribution assembly 220 form a separation into a plurality of process regions 250. The process regions are roughly defined around the individual gas ports 125, 135 with the gas curtain 150 between 250. The embodiment shown in FIG. 5 makes up eight separate process regions 250 with eight separate gas curtains 150 between. A processing chamber can have at least two process region. In some embodiments, there are at least three, four, five, six, seven, eight, nine, 10, 11 or 12 process regions.

During processing a substrate may be exposed to more than one process region 250 at any given time. However, the portions that are exposed to the different process regions will have a gas curtain separating the two. For example, if the leading edge of a substrate enters a process region including the second gas port 135, a middle portion of the substrate will be under a gas curtain 150 and the trailing edge of the substrate will be in a process region including the first reactive gas port 125.

A factory interface 280, which can be, for example, a load lock chamber, is shown connected to the processing chamber 100. A substrate 60 is shown superimposed over the gas distribution assembly 220 to provide a frame of reference. The substrate 60 may often sit on a susceptor assembly to be held near the front surface 121 of the gas distribution assembly 120. The substrate 60 is loaded via the factory interface 280 into the processing chamber 100 onto a substrate support or susceptor assembly (see FIG. 3). The substrate 60 can be shown positioned within a process region because the substrate is located adjacent the first reactive gas port 125 and between two gas curtains 150a, 150b. Rotating the substrate 60 along path 127 will move the substrate counter-clockwise around the processing chamber 100. Thus, the substrate 60 will be exposed to the first process region 250a through the eighth process region 250h, including all process regions between.

Embodiments of the disclosure are directed to processing methods comprising a processing chamber 100 with a plurality of process regions 250a-250h with each process region separated from an adjacent region by a gas curtain 150. For example, the processing chamber shown in FIG. 5. The number of gas curtains and process regions within the processing chamber can be any suitable number depending on the arrangement of gas flows. The embodiment shown in FIG. 5 has eight gas curtains 150 and eight process regions 250a-250h. The number of gas curtains is generally equal to or greater than the number of process regions.

A plurality of substrates 60 are positioned on a substrate support, for example, the susceptor assembly 140 shown FIGS. 1 and 2. The plurality of substrates 60 are rotated around the process regions for processing. Generally, the gas curtains 150 are engaged (gas flowing and vacuum on) throughout processing including periods when no reactive gas is flowing into the chamber.

A first reactive gas A is flowed into one or more of the process regions 250 while an inert gas is flowed into any process region 250 which does not have a first reactive gas A flowing into it. For example if the first reactive gas is flowing into process regions 250b through process region 250h, an inert gas would be flowing into process region 250a. The inert gas can be flowed through the first reactive gas port 125 or the second gas port 135.

The inert gas flow within the process regions can be constant or varied. In some embodiments, the reactive gas is co-flowed with an inert gas. The inert gas will act as a carrier and diluent. Since the amount of reactive gas, relative to the carrier gas, is small, co-flowing may make balancing the gas pressures between the process regions easier by decreasing the differences in pressure between adjacent regions.

Accordingly, one or more embodiments of the disclosure are directed to processing methods utilizing a batch processing chamber like that shown in FIG. 5. A substrate 60 is placed into the processing chamber which has a plurality of sections 250, each section separated from adjacent section by a gas curtain 150.

In some embodiments, a substrate surface is exposed to a first process condition followed by exposure to a second process condition. As used in this manner, the term “process condition” refers to the chemical environment, temperature and pressure. The first process condition comprises a first reactive gas and a second reactive gas. The first reactive gas and the second reactive gas are spontaneously reactive under the process conditions (e.g., temperature and pressure). The second reactive gas is provided in an amount that is less than a full amount that would be used for a chemical vapor deposition (CVD) process.

In a time-domain process, the after exposure to the first process condition, the processing chamber is purged to replace the first process condition with an inert environment. This also removes by-products from the reaction of the first reactive gas and the second reactive gas. In a spatial ALD process, like one that uses a chamber shown in FIG. 5, after exposure to the first process condition, the substrate can be laterally moved through a gas curtain to a second process region of the processing chamber. The gas curtain locally purges the first process condition from the substrate surface to replace the first process condition existing in the first process region. The gas curtain comprises one or more of a purge gas stream and/or a vacuum region. In some embodiments, as shown in FIG. 5, the gas curtain comprises a purge gas stream bounded on either side by a vacuum region so that the substrate surface is exposed to, in order, a vacuum region, a purge gas stream and a second vacuum region between each of the process regions of the processing chamber.

After exposure to the first process condition and purging the substrate surface is exposed to a second process condition. The second process condition can be formed in the process chamber (time-domain ALD) or in a second process region of the processing chamber (spatial ALD). The second process condition comprises the second reactive gas. In some embodiments, the second process condition consists essentially of the second reactive gas. As used in this regard, the term “consists essentially of” means that the reactive species of the second reactive gas makes up greater than or equal to about 95%, 98% or 99% of the stated species on a molar basis. The percentage does not include inert gases, diluent gases or carrier gases.

After exposure to the second reactive gas, the substrate surface or processing chamber is purged of the second process condition. This can be performed by purging the entire process chamber (i.e., in a time-domain process) or moving the substrate through a gas curtain to a different region of the processing chamber (i.e., in a spatial process).

Some embodiments of the disclosure enhance the growth rates by bleeding H₂ into the WF₆ zone in a controlled manner (first process condition). In this enhanced spatial ALD, the H₂ zone remains the same, having only H₂ and in some cases argon as well (second process condition). The WF₆ zone now has both WF₆ and H₂. In some embodiments, argon is present as well.

Growth rates (also called deposition rates) of greater than 0.2 Å/cycle may be realized. In an effort to enhance growth rate to beyond 0.2 Å/cycle while maintaining step coverage, a controlled amount of H₂ or an H₂/inert mixture is introduced into the WF₆ zone(s) as well. This is referred to as enhanced spatial ALD. In some embodiments, the deposition rate is in the range of about 0.2 Å/cycle to about 1 Å/cycle.

In some embodiments, the first process condition comprises WF₆. The first process condition of some embodiments comprises WF₆, H₂, and an optional inert gas such as argon. In some embodiments, the second process condition comprises H₂ and an optional inert gas such as argon.

In an exemplary embodiment, the first process condition comprises WF₆ with a total flow rate in the range of about 10 to about 1000 sccm, or in the range of about 50 to about 500 sccm, or about 100 sccm. The H₂ flow of the first process condition is in the range of about 1 to about 100 sccm, or about 10 sccm. The argon flow of the first process condition is in the range of about 0 to about 10000 sccm, or in the range of about 100 to about 5000 sccm, or in the range of about 500 to about 1000 sccm, or about 890 sccm.

In some embodiments, the second process condition comprises or consists essentially of a mixture of H₂/Ar. The percentage of H₂ in the mixture can be in the range of about 1 to about 99%, or in the range of about 1 to about 80%, or in the range of about 1 to about 60%, or in the range of about 2 to about 40%, or in the range of about 3 to about 20%, or in the range of about 3 to about 10%, or about 4%.

The total H₂/Ar mixture flow can be in the range of about 1 to about 10000 sccm, or in the range of about 10 to about 1000 sccm, or in the range of about 100 to about 500 sccm, or in about 250 sccm. The total H₂ flow can be in the range of about 1 to about 10000 sccm, or in the range of about 100 to about 5000 sccm, or in the range of about 1000 to about 4000 sccm, or about 2000 sccm. The total amount of argon flow can be in the range of about 0 to about 10000 sccm. If no argon co-flow is used, the flow is 0 sccm.

The substrate temperature can be adjusted and maintained based on the precursors being used. In some embodiments, the temperature of the substrate is in the range of about 200° C. to about 700° C., or in the range of about 300° C. to about 500° C., or in the range of about 325° C. to about 400° C., or about 350° C.

Suitable tungsten precursors for use with the first process condition include, but are not limited, to WF₆, WCl₆, WCl₅, WOCl₄, W₂Cl₁₀, WCl₄, bis(cyclopentadienyl)tungsten(IV) chloride hydride and/or combinations thereof. Suitable molybdenum precursors for use with the first process condition include, but are not limited to, MoF₆, MoCl₅, MoOCl₄, MoCl₃ and/or combinations thereof.

Exposure to the first process condition and the second process condition can be repeated to deposit a film having a predetermined thickness. In a time-domain process, the processing chamber is purged between each process condition exposure. In a spatial process, the substrate is moved among different process regions of the processing chamber where different process regions have different process conditions. For example, referring to FIG. 5, process regions 250a, 250c, 250e and 250g may have the first process condition and process regions 250b, 250d, 250f and 250h may have the second process condition. A substrate rotated through a complete circle would be exposed to four repeated sequences of the first process condition and the second process condition.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, annealing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, anneal, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In atomic layer deposition type chambers, the substrate can be exposed to the first and second precursors either spatially or temporally separated processes. Temporal ALD is a traditional process in which the first precursor flows into the chamber to react with the surface. The first precursor is purged from the chamber before flowing the second precursor. In spatial ALD, both the first and second precursors are simultaneously flowed to the chamber but are separated spatially so that there is a region between the flows that prevents mixing of the precursors. In spatial ALD, the substrate is moved relative to the gas distribution plate, or vice-versa.

In embodiments, where one or more of the parts of the methods takes place in one chamber, the process may be a spatial ALD process. Although one or more of the chemistries described above may not be compatible (i.e., result in reaction other than on the substrate surface and/or deposit on the chamber), spatial separation ensures that the reagents are not exposed to each in the gas phase. For example, temporal ALD involves the purging the deposition chamber. However, in practice it is sometimes not possible to purge the excess reagent out of the chamber before flowing in additional regent. Therefore, any leftover reagent in the chamber may react. With spatial separation, excess reagent does not need to be purged, and cross-contamination is limited. Furthermore, a lot of time can be used to purge a chamber, and therefore throughput can be increased by eliminating the purge step.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method comprising:
exposing a substrate surface to a first process condition comprising a first reactive gas and a second reactive gas; and
exposing the substrate surface to a second process condition comprising the second reactive gas,
wherein the first process condition comprises less than a full amount of the second reactive gas for CVD.

2. The method of claim 1, wherein the first reactive gas comprises WF₆.

3. The method of claim 2, wherein the second reactive gas comprises H₂.

4. The method of claim 1, wherein the second reactive gas is pulsed into the first reactive gas in the first process condition.

5. The method of claim 1, wherein the second reactive gas is continuously flowed into the first reactive gas in the first process condition.

6. The method of claim 1, wherein the first reactive gas and the second reactive gas in the first process condition are mixed prior to flowing into a process region of a processing chamber.

7. The method of claim 1, wherein the second reactive gas comprises in the range of about 1 to about 10% of the first reactive gas in the first process condition.

8. The method of claim 1, wherein a film is deposited with a deposition rate in the range of about 0.2 to about 1 Å/cycle.

9. The method of claim 1, further comprising repeated exposure to the first process condition and the second process condition.

10. The method of claim 1, further comprising laterally moving the substrate surface through a gas curtain from the first process condition to the second process condition.

11. A method comprising:
exposing a substrate surface to a first process condition comprising a first reactive gas and a second reactive gas, the first reactive gas and the second reactive gas are spontaneously reactive; and
exposing the substrate surface to a second process condition consisting essentially of the second reactive gas,
wherein the first process condition comprises less than a full amount of the second reactive gas for CVD.

12. The method of claim 11, wherein the first reactive gas comprises WF₆.

13. The method of claim 12, wherein the second reactive gas consists essentially of H₂.

14. The method of claim 11, wherein the second reactive gas is pulsed into the first reactive gas in the first process condition.

15. The method of claim 11, wherein the second reactive gas is continuously flowed into the first reactive gas in the first process condition.

16. The method of claim 11, wherein the first reactive gas and the second reactive gas in the first process condition are mixed prior to flowing into a process region of a processing chamber.

17. The method of claim 11, wherein the second reactive gas comprises in the range of about 1 to about 10% of the first reactive gas in the first process condition.

18. The method of claim 11, wherein a film is deposited with a deposition rate in the range of about 0.2 to about 1 Å/cycle.

19. The method of claim 11, further comprising repeated exposure to the first process condition and the second process condition.

20. A method comprising:
exposing a substrate surface to a first process condition in a first process region of a processing chamber, the first process condition comprising a constant flow of a first reactive gas comprising WF₆ and a pulsed flow of a second reactive gas consisting essentially of H₂, the second reactive gas pulsed so that there is less than a full amount of the second reactive gas for CVD;
laterally moving the substrate through a gas curtain from the first process region to a second process region of the processing chamber, the gas curtain comprising one or more of a purge gas stream and/or a vacuum region;
exposing the substrate surface to a second process condition in the second process region, the second process condition consisting essentially of the H₂;
laterally moving the substrate through a gas curtain from the second process region, the gas curtain comprising one or more of a purge gas stream and/or a vacuum region; and
repeating exposures to the first process condition and the second process condition to deposit a film of a predetermined thickness.
